(19) United States
(12) Patent Application Publication
(10) Pub. No.: US 2009/0025970 A1
(43) Pub. Date: Jan. 29, 2009

(54) Multilayer Wiring Board, and Electronic Module and Electronic Device Including the Multilayer Wiring Board

(75) Inventor: Nobuyoshi Yanagisawa, Osaka (JP)

Correspondence Address: EDWARDS ANGELL PALMER & DODGE LLP, P.O. BOX 55874, BOSTON, MA, 02205, US

(73) Assignee: Sharp Kabushiki Kaisha, Osaka (JP)

(21) Appl. No.: 12/087,091

(22) PCT Filed: Nov. 28, 2006
(86) PCT No.: PCT/JP2006/323721

§ 371 Date: Jun. 24, 2008

(30) Foreign Application Priority Data
Dec. 27, 2005 (JP) 2005-376477

(51) Int. Cl. H05K 1/11; H05K 1/16

(52) U.S. Cl. 174/260; 174/262; 174/263

(57) ABSTRACT

A multilayer wiring board (1) of the present invention provided in a camera module has a sandwiched wiring layer (13) between opened wiring layers (11) having openings (12). The openings (12) formed in the opened wiring layers (11) form a through hole (12a) which penetrates the opened wiring layer (11) in the direction in which the opened wiring layers (11) are stacked on top of each other. The sandwiched wiring layer (13) overlaps at least part of the opening (12) of the opened wiring layer (11) and has a blocking section (13a) which blocks the through hole (12a). Therefore, it is possible to mitigate thermal stress applied to the multilayer wiring board, while maintaining the freedom of wiring design.

### TECHNICAL FIELD

The present invention relates to a multilayer wiring board that mitigates thermal stress while ensuring the freedom of wiring design, and an electronic module and an electronic device including the multilayer wiring board.

### BACKGROUND ART

Conventionally, soldering of a semiconductor (integrated circuit (IC) etc.) and/or other electronic component onto a board was performed in the following manner. That is, the board with the electronic component was put into a reflow furnace so that solder printed in advance on the board was melted for soldering.

At the heating in the reflow furnace and in the course of cooling to room temperature after the heating, thermal stress is applied to the electronic component and the board due to difference in thermal expansion between the board and the electronic component to be mounted onto the board. This raises the problems such as detachment of a portion of the board where terminals are soldered (solder-joint section), fractures of a wiring pattern formed on the board, warpage of the board, and/or cracks in a package of the electronic component. Even in a case where no fractures and/or cracks occur, solder short circuits (bridging) and solder detachment can occur. This significantly decreases the quality of soldering.

In order to solve the above problems, measures for mitigation of such stress have been taken for an IC package, for example. FIGS. 10 and 11 are top views of the conventional IC packages. FIG. 12 is an explanatory view of thermal stress applied to the IC packages of FIGS. 10 and 11.

As for IC packages for use in surface-mounting, such as QFP (Quad Flat Package) illustrated in FIG. 10 and SOP (Small Outline Package) illustrated in FIG. 11, a lead portion 110 has the function of mitigating stress, as illustrated in FIG. 12.

For example, Patent document 1 discloses another stress mitigation method of an IC package having a lead portion. FIG. 13(a) is a top view of a board of Patent document 1. FIG. 13(b) is a cross-sectional view illustrating the module structure of Patent document 1. In the arrangement of Patent document 1, a slit (cut) 102 is formed on a board 101 on which an IC package 111 having the lead portion 110 is mounted, as illustrated in FIGS. 13(a) and 13(b). In Patent document 1, the slit 102 prevents cracks of the IC package 111, prevents the occurrence of poor electrical continuity, and misalignment of the board 101 and the IC package 111.

Patent document 2 discloses the arrangement illustrated in FIG. 14, i.e. the arrangement in which an extra board 202 formed around a main board 201 has a reinforcing layer section 203 formed thereon so that thickness of the extra board 202 is larger than that of the main board 201. In this arrangement, the extra board 202 is made thicker by the reinforcing layer section 203 than the main board 201 so that warpage of the main board 201 is prevented.

[Patent document 1]

Japanese Unexamined Patent Publication No. 296390/1990 (Tokukaihei 2-296390; published on Dec. 6, 1990)

[Patent document 2]

Japanese Unexamined Patent Publication No. 7453/2001 (Tokukai 2001-7453; published on Jan. 12, 2001)

### DISCLOSURE OF INVENTION

As IC packages for high-density mounting used at a high frequency, the foregoing QFP and SOP have been recently replaced by QFN (Quad Flat No-Lead) illustrated in FIG. 15 and LCC (Leaded Chip Carrier) illustrated in FIG. 16, and the like. However, these packages are arranged such that solder mount terminals are formed directly on the packages, and the terminals and the board are soldered to each other. That is, unlike the QFT and SOP, these packages have no lead portions and therefore have no stress-absorbing section. With this arrangement, the stress caused by difference in thermal expansion is applied to a solder joint section 113, as illustrated in FIG. 17. As a result, the aforementioned problems such as detachment of the solder joint section 113 occur.

Furthermore, in the arrangement disclosed in Patent document 1, the slit 102 penetrates the board 101. Therefore, the wiring cannot be formed in the area corresponding to slit 102. This raises the problem that a wiring pattern to be formed on the board 101 is restricted.

In addition, Patent document 2 adopts the method in which, in order to prevent warpage of the main board 201, the extra board 202 formed around a frame of the main board 201 is reinforced with the reinforcing layer section 203, and the frame is separated at the time when the frame is cooled sufficiently to room temperature. That is, the extra board 202 and the reinforcing layer section 203 are separated from the main board 201 along a division line 204 after soldering. This requires separation of the extra board 202, which is waste, and thus increases loss on disposal. In addition, the formation of the reinforcing layer section 203 that can prevent warpage of the main board 201 requires prior estimation of stress caused by difference in thermal expansion at the stage of design of the extra board 202. This causes a complicated manufacturing process and an extremely poor productivity. Thus, the arrangement disclosed in Patent document 2 is not suitable for practical use since it raises many problems in manufacturing multilayer wiring boards.

The present invention has been attained in view of the problem associated with the conventional art, and an object of the present invention is to provide a multilayer wiring board that mitigates thermal stress while ensuring the freedom of wiring design, and an electronic module and the like including the multilayer wiring board.

In order to solve the above problem, a multilayer wiring board of the present invention includes: a plurality of opened wiring layers being stacked on top of each other and respectively having openings, which form a through hole penetrating in a direction in which the opened wiring layers are stacked; and a sandwiched wiring layer disposed between the opened wiring layers, wherein the sandwiched wiring layer overlaps at least part of the opening of the opened wiring layer and has a blocking section that blocks the through hole.

A multilayer wiring board of the present invention is composed of a plurality of opened wiring layers and at least one sandwiched wiring layer. When the opened wiring layers are overlaid (bundled), the openings formed in the opened wiring layers form a through hole that penetrates in the direction where they are overlaid. The sandwiched wiring layer has the blocking section that blocks at least part of the through hole.

According to the above arrangement, the opened wiring layer has an opening, which mitigates thermal stress applied to the multilayer wiring board. Furthermore, the above arrangement is suitable for practical use since it does not produce loss on disposal of the extra board and others, unlike Patent document 2.

Particularly, according to the above arrangement, the blocking section of the sandwiched wiring layer overlaps at least part of the opening of the opened wiring layer. That is, the blocking section is exposed from the opening of the opened wiring layer. This secures an area for wiring due to the sandwiched wiring layer (blocking section) even when the opened wiring layer has an opening. Therefore, the freedom of wiring pattern design (wiring design) is not decreased.

Thus, while the sandwiched wiring layer ensures the freedom of wiring design, the opening of the opened wiring layer mitigates thermal stress. This makes it possible to maintain cracks of the electronic component, warpage of the board, and the quality of solder joint.

Note that the thermal stress mainly indicates (i) stress caused by uneven thermal conduction due to difference in shape between the multilayer wiring board and the electronic component (such as IC package) mounted thereon and (ii) stress caused by difference in thermal expansion coefficient between materials (mainly resins) used for the multilayer wiring board and the electronic component. The thermal stress is caused by, for example, contraction of the multilayer wiring board and the electronic component due to heating and expansion thereof due to cooling after heating.

An electronic module of the present invention is arranged such that an electronic component is mounted on any one of the multilayer wiring board of the present invention. Further, an electronic device of the present invention includes the electronic module. With this arrangement, it is possible to realize an electronic module and an electronic device that allows for mitigation of stress (thermal stress) caused by difference in thermal expansion between the multilayer wiring board and the electronic component.

As described above, the present invention is arranged such that the sandwiched wiring layer disposed between the opened wiring layers overlaps at least part of the opening of the opened wiring layer and has a blocking section that blocks the through hole. Therefore, the present invention brings the effect of mitigating thermal stress while maintaining the freedom of wiring design.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1 is a top view of a multilayer wiring board according to the present invention.

FIG. 2 is an exploded view of the multilayer wiring board of FIG. 1.

FIG. 3(a) is a cross-sectional view of the multilayer wiring board, viewed along line A-A in FIG. 1.

FIG. 3(b) is a cross-sectional view of the multilayer wiring board, viewed along line B-B in FIG. 1.

FIG. 4 is a partial cross-sectional view of a camera module according to the present invention.

FIG. 5 is an explanatory view of a stress applied to the opened wiring layers.

FIG. 6(a) is a top view of another multilayer wiring board according to the present invention.

FIG. 6(b) is a cross-sectional view of the multilayer wiring board, viewed along line A-A in FIG. 6(a).

FIG. 6(c) is a cross-sectional view of the multilayer wiring board, viewed along line B-B in FIG. 6(a).

FIG. 7 is an exploded view of the multilayer wiring board of FIG. 6(a).

FIG. 8 is a top view of still another multilayer wiring board according to the present invention.

FIG. 9 is a top view of yet another multilayer wiring board according to the present invention.

FIG. 10 is a top view of a QFP.

FIG. 11 is a top view of an SOP.

FIG. 12 is an explanatory view of thermal stress applied to QFP and SOP.

FIG. 13(a) is a top view of a board having a module structure in Patent document 1.

FIG. 13(b) is a cross-sectional view of the module structure of Patent document 1.

FIG. 14 is a cross-sectional view of a multilayer wiring board disclosed in Patent document 2.

FIG. 15 is a top view of a QFN.

FIG. 16 is a top view of an LCC.

FIG. 17 is an explanatory view of thermal stress applied to QFN and LCC.

### BEST MODE FOR CARRYING OUT THE INVENTION

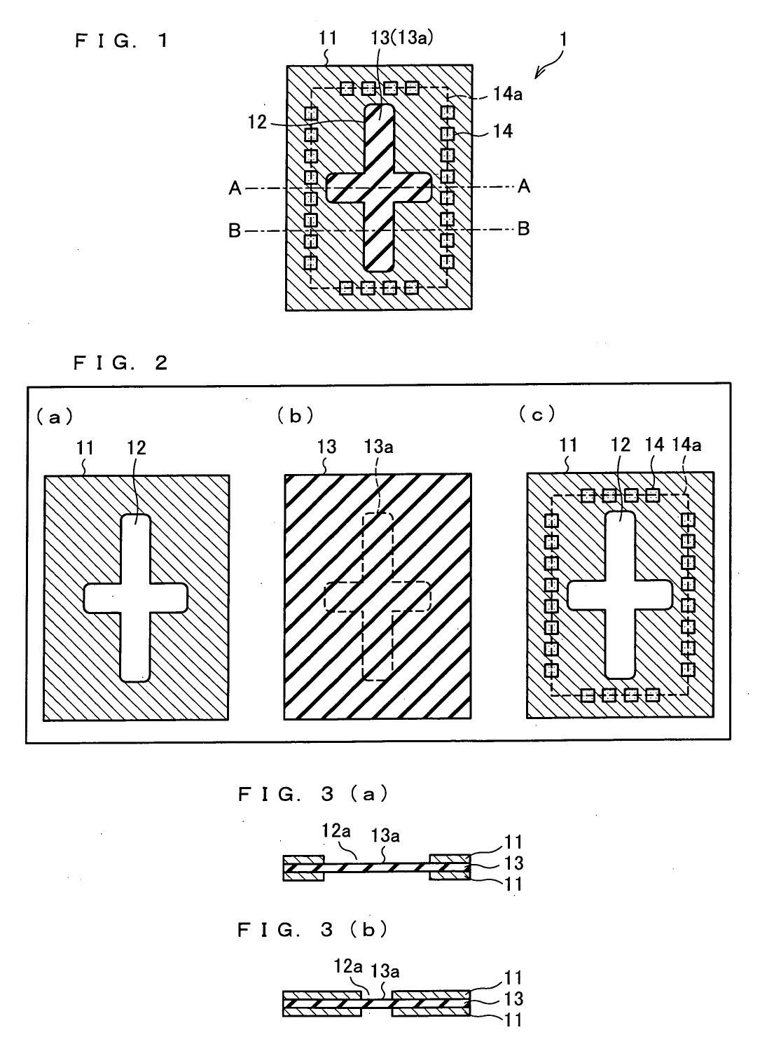

The following will describe an embodiment of the present invention with reference to FIGS. 1 through 9. It should be noted that the present invention is not limited by the following description.

The following description assumes that an electronic module of the present invention is, for example, a camera module which is installed in an electronic device such as a mobile phone and a digital still camera.

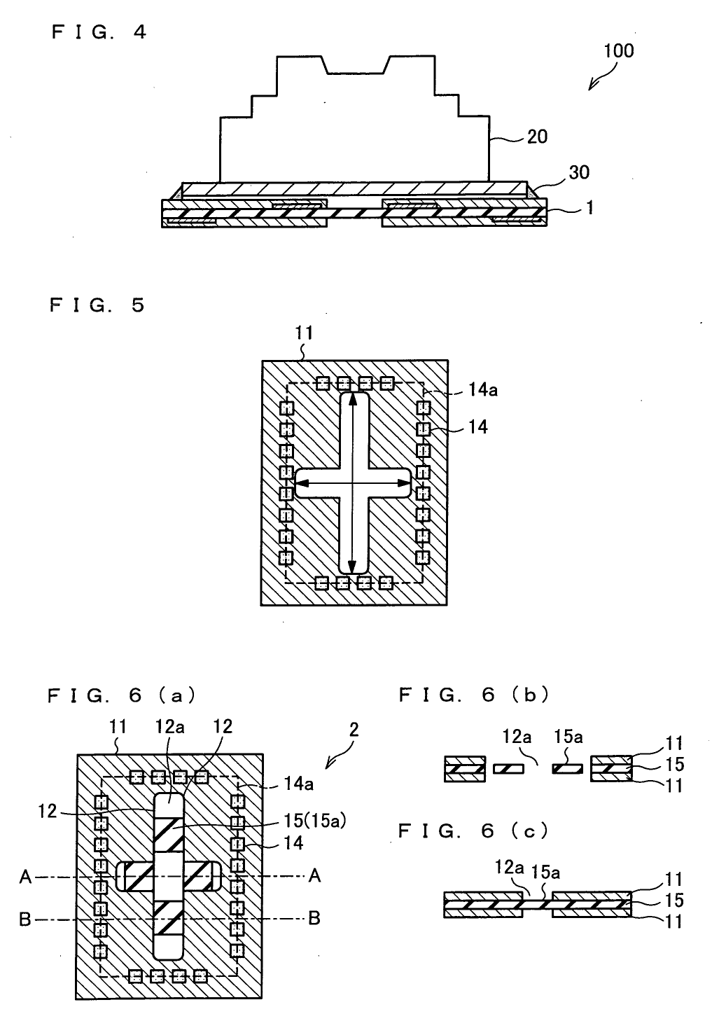

FIG. 4 is a partial cross-sectional view of a camera module 100 of the present embodiment. As illustrated in FIG. 4, the camera module 100 is arranged such that a lens 20 is soldered onto the surface of a multilayer wiring board 1 via a solder joint section 30.

The multilayer wiring board 1 is a board onto which the lens 20 is mounted, and has the structure in which a plurality of wiring layers (wiring substrates) are stacked on top each other. FIG. 1 is a top view of the multilayer wiring board 1 of the present embodiment. As illustrated in FIG. 1, the multilayer wiring board 1 is composed of opened wiring layers 11 and a sandwiched wiring layer 13. On the surface of the multilayer wiring board 1, a plurality of terminals 14 are provided through which the lens 20 is mounted. The lens 20 is mounted in a terminal-formed area 14a in which the terminals 14 are provided. Details of the multilayer wiring board 1 will be described later.

The lens 20 is an optical element such as an image sensor that is installed in a mobile phone, a digital still camera, or the like. On the back surface (bottom surface) of the camera module 100, a plurality of connection terminals are provided corresponding to the terminals 14 of the multilayer wiring board 1. The terminals 14 of the multilayer wiring board 1 and the connection terminals of the lens 20 are arranged so as to face each other and joined to each other via a solder joint section 30.

The following will describe details of the multilayer wiring board 1, which is the characteristic part of the present invention. FIG. 2 is an exploded view of the multilayer wiring board 1. FIG. 3(a) is a cross-sectional view of the multilayer wiring board 1, viewed along line A-A in FIG. 1. FIG. 3(b) is a cross-sectional view of the multilayer wiring board 1, viewed along line B-B in FIG. 1.

As illustrated in FIG. 2, the multilayer wiring board 1 of the present embodiment is composed of two opened wiring layers 11 (FIGS. 2(a) and 2(c)) and one sandwiched wiring layer 13 (FIG. 2(b)), which is sandwiched between the opened wiring layers 11. There is electrical continuity between the opened wiring layers 11 and the sandwiched wiring layer 13 through via holes (not shown). On the surface of one of the opened wiring layers 11 (on the surface of the opened wiring layer 11 onto which the lens 20 is mounted), the terminals 14 through which the lens 20 is mounted are provided. Note that the wiring layers constructing the multilayer wiring board 1 are of substantially the same size.

As illustrated in (a) of FIG. 2, an opening 12 in the shape of a cross is formed in the center of the opened wiring layer 11. The two opened wiring layers 11 used in the present embodiment are identical with each other. With this arrangement, when the two opened wiring layers 11 are overlaid on each other, the openings 12 formed in the opened wiring layers 11 form a through hole 12a which penetrates the opened wiring layers 11 in the direction in which the layers are stacked (see FIGS. 3(a) and 3(b)).

As illustrated in (b) of FIG. 2, the sandwiched wiring layer 13 has no opening therein. With this arrangement, when the sandwiched wiring layer 13 is made sandwiched between the opened wiring layers 11, the sandwiched wiring layer 13 overlaps the whole area of the openings 12 of the opened wiring layers 11, as illustrated in FIG. 1.

With this arrangement, the portion of the sandwiched wiring layer 13 as indicated by an dashed line in (b) of FIG. 2, i.e. the portion of the sandwiched wiring layer 13 which portion coincides with the openings 12 of the opened wiring layers 11 corresponds to a blocking section 13a. The blocking section 13a blocks the through hole 12a. That is, the through hole 12a, which forms when the opened wiring layers 11 are overlaid on each other, is blocked by the blocking section 13a of the sandwiched wiring layer 13, as illustrated in cross-sectional views of FIGS. 3(a) and 3(b). In other words, the openings 12 in the surfaces of the opened wiring layers 11 which surfaces face each other (surfaces of the opened wiring layers 11 which surfaces are in contact with the sandwiched wiring layer 13) are closed by the blocking section 13a. Thus, the multilayer wiring board 1 has (i) a multilayer wiring part in which the opened wiring layer 11, the sandwiched wiring layer 13 and the opened wiring layers 11 are stacked in this order and (ii) a single-layer wiring part which is constituted by the sandwiched wiring layer 13 alone. On the single-layer wiring part (blocking section 13a), signal lines, a power source, a ground, and others are provided.

On the opened wiring layers 11 and the sandwiched wiring layer 13, wiring patterns (signal lines) (not shown) are formed. It is preferable that a solder resist as an insulation protective layer is laminated on the wiring pattern by thermocompression bonding. The insulation protective layer is made from polyimide resin, for example. Lamination of the solder resist enhances resistance to flexibility.

The multilayer wiring board 1 arranged as above can be fabricated by thermocompression bonding of the opened wiring layers 11 and the sandwiched wiring layer 13. Then, solder is applied onto the terminals 14 of the multilayer wiring board 1, after which the solder is melt while the lens 20 is mounted thereon. In this manner, the camera module 100 can be manufactured. Further, through the use of the self-alignment effect of the solder, it is possible to align the multilayer wiring board 1 and the lens 20 with high precision.

Now, the function of the openings 12 formed in the opened wiring layers 11 is described. FIG. 5 is an explanatory view of a stress applied to the opened wiring layers 11. Thermal expansion coefficient of the multilayer wiring board 1 is different from that of the electronic component (lens 20) which is mounted on the multilayer wiring board 1. For this reason, a high thermal stress is applied to a terminal-formed area 14a, especially to an area between the terminals 14 which are arranged at the opposite positions (area surrounded by the terminals which are arranged on respectively opposite sides of the arrows in FIG. 5), as illustrated in FIG. 5.

In view of this, the multilayer wiring board 1 of the present embodiment is arranged such that the openings 12 of the opened wiring layers 11 are formed inside the terminal-formed area 14a. This makes it possible to mitigate thermal stress applied to the inside of the terminal-formed area 14a. Especially, in the present embodiment, the openings 12 are formed so as to cut all the respective lines that couple the corresponding terminals 14 arranged at the opposite positions. This arrangement particularly brings a high degree of effectiveness of mitigating the thermal stress applied to the inside of the terminal-formed area 14a.

An effective way to enhance the effect of mitigating the thermal stress is to increase an area of the openings 12 of the opened wiring layers 11. On the other hand, too large an area of the openings 12 decreases the degree of freedom in designing the wiring patterns formed on the opened wiring layers 11 (wiring design).

However, the multilayer wiring board 1 of the present embodiment is arranged such that the area of the blocking section 13a of the sandwiched wiring layer 13 coincides with the whole area of the opening 12 of the opened wiring layer 11, and part of the sandwiched wiring layer 13 (i.e. the blocking section 13a) is exposed from the openings 12. Further, there is continuity between the opened wiring layers 11 and the sandwiched wiring layer 13. This allows the sandwiched wiring layer 13 (blocking section 13a) to secure an area for the wiring even though the openings 12 are formed in the opened wiring layers 11. Therefore, the freedom of wiring pattern designing (wiring design) is not decreased.

Further, the multilayer wiring board 1 of the present embodiment is preferably arranged such that the sandwiched wiring layer 13 is more flexible than the opened wiring layers 11. For example, the sandwiched wiring layer 13 is preferably a flexible substrate (FPC: flexible printed circuit substrate), a film substrate, or the like. In this arrangement, the opened wiring layers 11 are relatively rigid, and the sandwiched wiring layer 13 is soft. That is, since the sandwiched wiring layer 13 has a higher flexibility, the blocking section 13a of the sandwiched wiring layer 13 enables mitigation (absorption) of thermal stress. Therefore, it is possible to further enhance the effect of mitigating thermal stress. In addition, the sandwiched wiring layer 13 itself enables stress mitigation without the formation of an aperture which will be described later in the sandwiched wiring layer 13, and ensures the freedom of wiring.

A material for the opened wiring layers 11 and the sandwiched wiring layer 13 includes, but is not particularly limited to, aramid, liquid crystal polymer, glass epoxy, or heat-resistant polyester, for example. In order to obtain more effective thermal stress mitigation, the sandwiched wiring layer 13 is preferably made from a flexible and heat-resistant material such as aramid. For example, the sandwiched wiring layer 13 can be a layer of a thin film made from a material such as aramid or polyimide resin with a wiring pattern formed thereon. The opened wiring layers 11 and the sandwiched wiring layer 13 may be made from the same material.

The sandwiched wiring layer 13 is thick enough to secure an area for the wiring at the minimum, and preferably thin enough to have a sufficient flexibility. However, the degree of thickness of the sandwiched wiring layer 13 is not particularly limited. Therefore, the sandwiched wiring layer 13 can be arranged thinner than the opened wiring layers 11 if the sandwiched wiring layer 13 meets such conditions.

In the above description, the multilayer wiring board 1 is composed of two opened wiring layers 11 and one sandwiched wiring layer 13. However, the structure of the multilayer wiring board 1 is not limited to this. The multilayer wiring board 1 may be composed of two or more opened wiring layers 11 and at least one sandwiched wiring layer 13.

As described above, in the multilayer wiring board 1 of the present embodiment, the openings 12 of the opened wiring layers 11 enables mitigation of thermal stress, while the sandwiched wiring layer 13 ensures the freedom of wiring design. Therefore, it is possible to maintain cracks of the electronic component, warpage of the board, and the quality of solder joint.

### [Alternative Arrangement Examples of Multilayer Wiring Board]

The following will describe alternative arrangements of a multilayer wiring board according to the present invention. Note that only differences from the multilayer wiring board 1 will be explained below, and the explanation of similarities will be omitted. In addition, components being the same as the components in the multilayer wiring board 1 and components having the same functions as those in the multilayer wiring board 1 are given the same reference numerals and explanations thereof are omitted here.

[Alternative Arrangement 1]

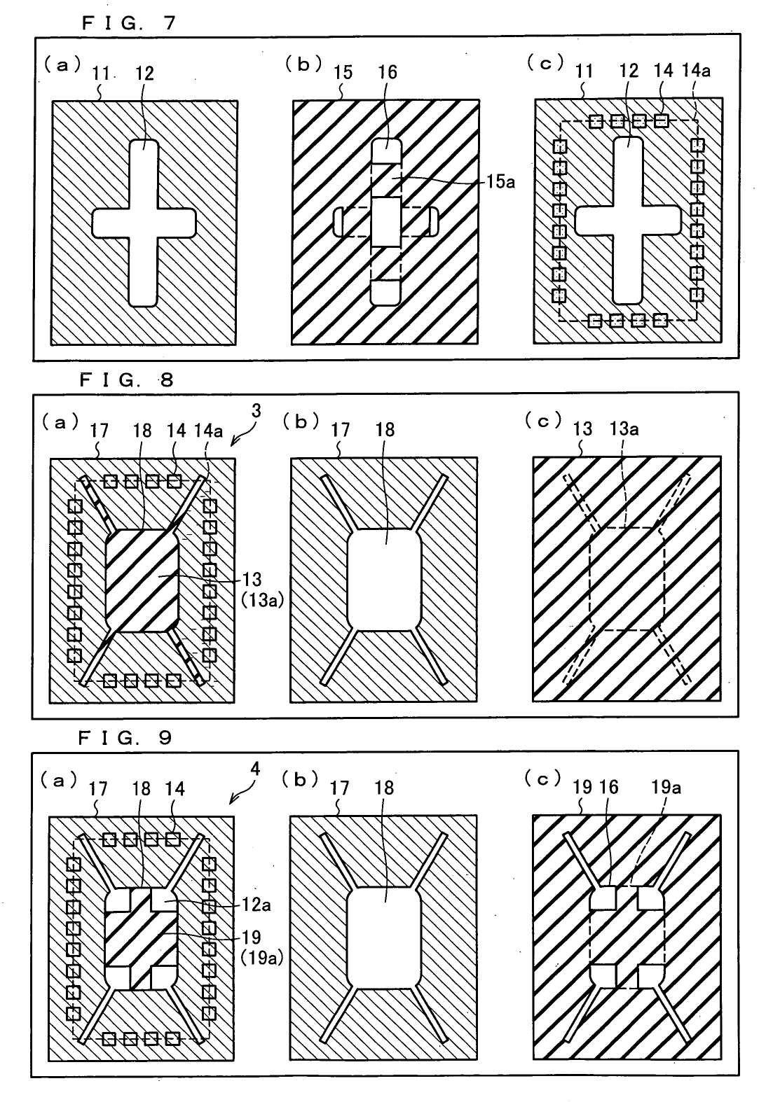

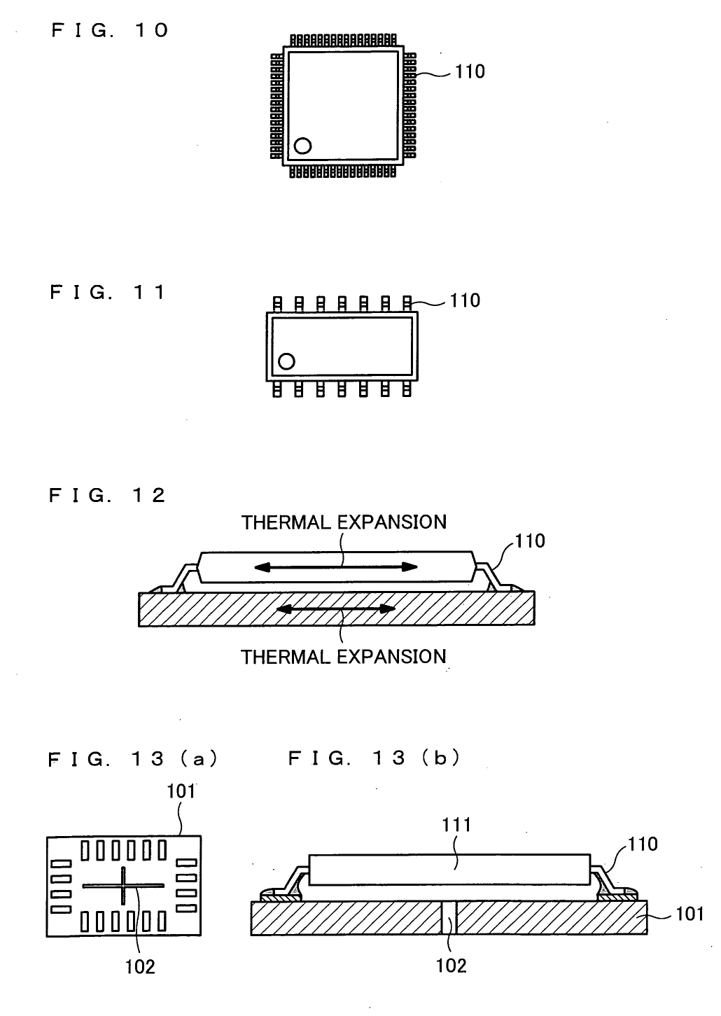

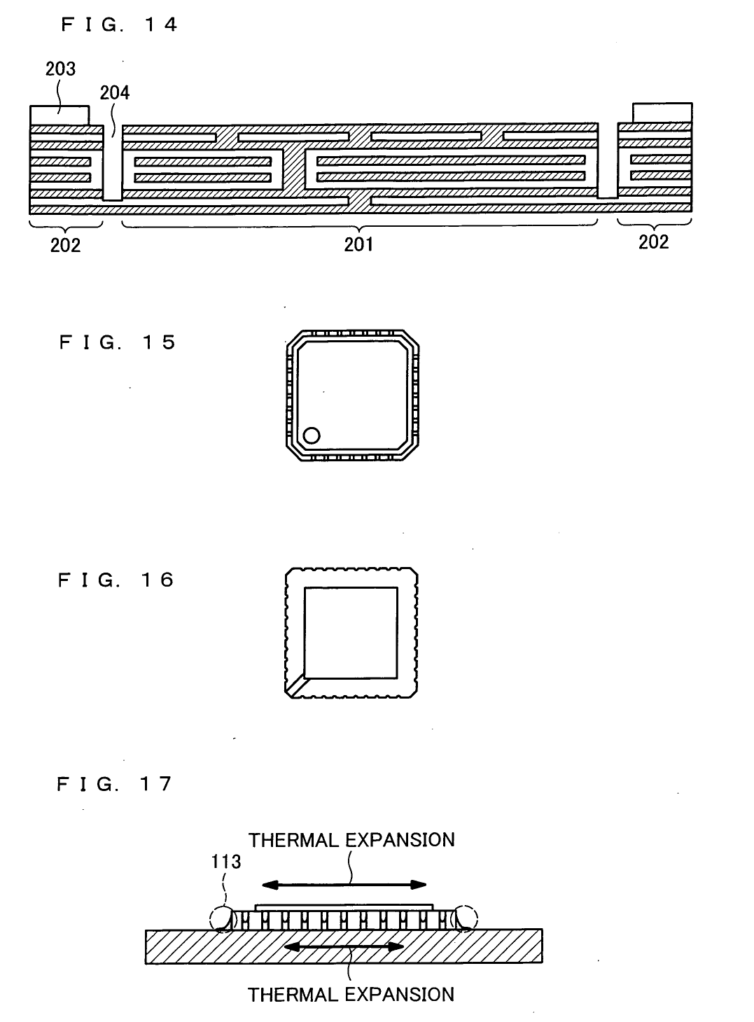

FIG. 6(a) is a top view of a multilayer wiring board 2. FIG. 6(b) is a cross-sectional view of the multilayer wiring board 2, viewed along line A-A in FIG. 6(a). FIG. 6(c) is a cross-sectional view of the multilayer wiring board 2, viewed along line B-B in FIG. 6(a). FIG. 7 is an exploded view of the multilayer wiring board 2 of FIG. 6(a).

As illustrated in (b) of FIG. 7, the multilayer wiring board 2 is different from the foregoing multilayer wiring board 1 in that an aperture 16 is formed in a sandwiched wiring layer 15.

Specifically, the multilayer wiring board 2 illustrated in FIG. 6(a) is composed of two opened wiring layers 11 ((a) and (c) of FIG. 7) and one sandwiched wiring layer 15 ((b) of FIG. 7), which is sandwiched between the two opened wiring layers 11, as illustrated in FIG. 7. There is electrical continuity between the opened wiring layers 11 and the sandwiched wiring layer 15 through via holes (not shown).

As described previously, each of the opened wiring layers 11 has an opening 12 in the shape of a cross, and the opening 12 is formed in the terminal-formed area 14a. When the two opened wiring layers 11 are overlaid on each other, the openings 12 formed in the opened wiring layers 11 form a through hole 12a, which penetrates the opened wiring layers 11 in the direction in which the layers are stacked.

As illustrated in (b) of FIG. 7, the sandwiched wiring layer 15 has the aperture 16. The aperture 16 is a section where part of the sandwiched wiring layer 15 lacks. The aperture 16 gets through to the openings 12 (through hole 12a). In the area of the sandwiched wiring layer 15 where the aperture 16 is not formed, the sandwiched wiring layer 15 overlaps the openings 12 of the opened wiring layers 11.

Thus, the multilayer wiring board 2, in which the sandwiched wiring layer 15 is sandwiched between the opened wiring layers 11, is arranged such that the sandwiched wiring layer 15 has (i) an area that overlaps the opened wiring layers 11 and (ii) an area that gets through to the openings 12 of the opened wiring layers 11, as illustrated in FIGS. 6(a) through 6(c).

In the area of the sandwiched wiring layer 15 indicated by a dashed line in (b) of FIG. 7, i.e. in the area that overlaps the openings 12 of the opened wiring layers 11, an area where the aperture 16 is formed does not block the through hole 12a, while an area where the aperture 16 is not formed blocks the through hole 12a. The area that blocks the through hole 12a is a blocking section 15a. That is, as illustrated in cross-sectional views of FIGS. 6(b) and 6(c), the through hole 12a, which forms when the opened wiring layers 11 are overlaid, is blocked by the blocking section 15a of the sandwiched wiring layer 15, and the through hole 12a is not blocked in the area where the aperture 16 is formed. In other words, the openings 12 in the surfaces of the opened wiring layers 11 which surfaces face each other (surfaces of the opened wiring layers 11 which surfaces are in contact with the sandwiched wiring layer 13) are closed by the blocking section 15a and become penetrated by means of the aperture 16.

Thus, the multilayer wiring board 2 has (i) a multilayer wiring part in which the opened wiring layer 11, the sandwiched wiring layer 15, the opened wiring layers 11 are stacked, (ii) a single-layer wiring part which is constituted by the sandwiched wiring layer 15 alone, and (iii) the through hole 12a where none of the wiring layers is not formed.

As described above, the multilayer wiring board 2 is arranged such that the aperture 16 is formed in the sandwiched wiring layer 15. This allows the aperture 16 to function similarly to the openings 12, thus mitigating thermal stress.

[Alternative Arrangement 2]

(a) of FIG. 8 is a top view of a whole multilayer wiring board 3. (b) of FIG. 8 is a top view (plan view) of an opened wiring layer 17 which is a constituent member of the multilayer wiring board 3. (c) of FIG. 8 is a top view (plan view) of a sandwiched wiring board 13 which is a constituent member of the multilayer wiring board 3. In (b) of FIG. 8, the opened wiring layer 17 having terminals 14 is omitted.

As illustrated in (b) of FIG. 8, the multilayer wiring board 3 is different from the foregoing multilayer wiring boards 1 and 2 in that an opening 18 is formed in the opened wiring layer 17.

More specifically, the multilayer wiring board 3 illustrated in (a) of FIG. 8 is composed of two opened wiring layers 17 illustrated in (b) of FIG. 8 and one sandwiched wiring layer 13 sandwiched between the opened wiring layers 17. There is electrical continuity between the opened wiring layers 17 and the sandwiched wiring layer 15 through via holes (not shown).

As illustrated in (a) and (b) of FIG. 8, each of the opened wiring layers 17 has the opening 18 in a terminal-formed area 14a, and the opening 18 extends from the inside of the terminal-formed area 14a to the outside thereof. More specifically, the opening 18 extending to the outside of the terminal-formed area 14a is formed so as to extend toward the outer edges (corners) of the opened wiring layer 17, passing through an intersection of lines of terminals, which lines are arranged along respectively different directions. It can be said that the opening 18 extends along diagonal lines of the terminal-formed area 14a since the terminal-formed area 14a is a quadrangle (rectangle). Also, it can be said that the opening 18 extends toward the corners of the opposed terminals 14 beyond the terminal-formed area 14a. Note that the lines of terminals arranged along respectively different directions can be also referred to as sides (imaginary matters) sharing an apex. As in the case with the foregoing opening 12, the whole opening 18 is formed so as to cut a line that couples the corresponding terminals arranged at opposite positions.

On the other hand, as in the case with the multilayer wiring board 1, the sandwiched wiring layer 13 has no opening. Therefore, the sandwiched wiring layer 13 overlaps the whole area of the opening 18 of the opened wiring layer 17, as illustrated in (a) of FIG. 8.

Thus, the multilayer wiring board 3 is arranged such that the opening 18 of the opened wiring layer 17 is formed so as to extend toward the outer edges of the opened wiring layer 17, passing through an intersection of lines of terminals, which lines are arranged along respectively different directions. This arrangement makes it possible to mitigate not only thermal stress applied to the area between the opposed terminals 14 but also thermal stress applied in the directions (diagonal directions) toward the intersection of the lines of terminals. Therefore, it is possible to further enhance the ability of mitigating thermal stress.

[Alternative Arrangement 3]

(a) of FIG. 9 is a top view of a multilayer wiring board 4. (b) of FIG. 9 is a top view (plan view) of an opened wiring layer 17 which is a constituent member of the multilayer wiring board 4. (c) of FIG. 9 is a top view (plan view) of a sandwiched wiring board 19 which is a constituent member of the multilayer wiring board 4. In (b) of FIG. 9, the opened wiring layer 17 having terminals 14 is omitted.

As illustrated in (a) of FIG. 9, the multilayer wiring board 4 is substantially the same as the multilayer wiring board 3 ((a) of FIG. 8), but is different from the multilayer wiring board 3 only in an aperture 16 of the sandwiched wiring layer 19, as illustrated in (c) of FIG. 9.

More specifically, as is the case with the multilayer wiring board 2, the sandwiched wiring layer 19 has the aperture 16, as illustrated in (c) of FIG. 9. The aperture 16 is a section where part of the sandwiched wiring layer 19 lacks. The aperture 16 gets through to the openings 18 (through hole 12a). In the area of the sandwiched wiring layer 19 where the aperture 16 is not formed, the sandwiched wiring layer 19 overlaps the openings 18 of the opened wiring layers 17, and a blocking section 19a is formed.

Thus, the multilayer wiring board 4 is arranged such that the sandwiched wiring layer 15 has the aperture 16. This allows the aperture 16 to function similarly to the openings 12, thus mitigating thermal stress.

Further, in the multilayer wiring board 4, the openings 18 of the opened wiring layer 17 is formed so as to extend toward the outer edges of the opened wiring layer 17, passing through an intersection of lines of terminals, which lines are arranged along respectively different directions. This arrangement makes it possible to mitigate not only thermal stress applied to the area between the opposed terminals 14 but also thermal stress applied in the directions (diagonal directions) toward the intersection of the lines of terminals. Therefore, it is possible to further enhance the ability of mitigating thermal stress.

As described above, a multilayer wiring board of the present invention includes: a plurality of opened wiring layers being stacked on top of each other and respectively having openings, which form a through hole penetrating in a direction in which the opened wiring layers are stacked; and a sandwiched wiring layer disposed between the opened wiring layers, wherein the sandwiched wiring layer overlaps at least part of the opening of the opened wiring layer and has a blocking section that blocks the through hole.

According to the above arrangement, the opened wiring layer has an opening, which mitigates thermal stress applied to the multilayer wiring board. Furthermore, the above arrangement is suitable for practical use since it does not produce loss on disposal of the extra board and others, unlike Patent document 2.

Particularly, according to the above arrangement, the blocking section of the sandwiched wiring layer overlaps at least part of the opening of the opened wiring layer. That is, the blocking section is exposed from the opening of the opened wiring layer. This secures an area for wiring due to the sandwiched wiring layer (blocking section) even when the opened wiring layer has an opening. Therefore, the freedom of wiring pattern design (wiring design) is not decreased.

Thus, while the sandwiched wiring layer ensures the freedom of wiring design, the opening of the opened wiring layer mitigates thermal stress. This makes it possible to maintain cracks of the electronic component, warpage of the board, and the quality of solder joint.

In the multilayer wiring board of the present invention, the blocking section is preferably formed so as to overlap the whole area of the opening of the opened wiring layer. This makes it possible to form the wiring in the whole area of the opening, thus further increasing the degree of freedom of wiring pattern design (wiring design).

In the multilayer wiring board of the present invention, the sandwiched wiring layer is preferably more flexible than the opened wiring layer. It is more preferable that the sandwiched wiring layer is a flexible substrate, like a flexible printed wiring board, for example.

According to the above arrangement, since the sandwiched wiring layer is more flexible than the opened wiring layer, the blocking section of the sandwiched wiring layer enables mitigation (absorption) of thermal stress. Therefore, the sandwiched wiring layer itself further enhances the effect of mitigating thermal stress.

In the multilayer wiring board of the present invention, the sandwiched wiring layer may have an aperture that gets through to the through hole.

According to the above arrangement, the sandwiched wiring layer has an aperture, which has the same function as the function of the opening of the opened wiring layer. That is, the aperture enables mitigation of thermal stress. This makes it possible to further enhances the effect of mitigating thermal stress.

The aperture may be formed in an area where wiring is unnecessary to form. The sandwiched wiring layer can be a rigid wiring layer since the aperture mitigates thermal stress. With the use of the sandwiched wiring layer having flexibility, the sandwiched wiring layer and the aperture enable mitigation of thermal stress. This further enhances the effect of mitigating thermal stress.

The multilayer wiring board of the present invention is preferably arranged such that it further includes terminals through which an electronic component is surface-mounted, and the opening of the opened wiring layer is formed in a terminal-formed area of the opened wiring layer. This allows the opening to mitigate an especially high thermal stress applied to the terminal-formed area.

The multilayer wiring board of the present invention may be arranged such that the opening of the opened wiring layer is formed so as to cut a line that couples the corresponding terminals arranged at opposite positions. With this arrangement, the opening is formed between the terminals arranged at opposite positions. This makes it possible to reliably mitigate thermal stress applied to the terminal-formed area.

The multilayer wiring board of the present invention may be arranged such that the opening of the opened wiring layer is formed so as to extend from an inside of a terminal-formed area toward outer edges of the opened wiring layer, passing through an intersection of lines of terminals, which lines are arranged along respectively different directions.

According to the above arrangement, the opening of the opened wiring layer is formed so as to extend from an inside of a terminal-formed area toward outer edges of the opened wiring layer, passing through an intersection of lines of terminals, which lines are arranged along respectively different directions. This arrangement makes it possible to mitigate not only thermal stress applied to the area between the opposed terminals but also thermal stress applied in the directions (diagonal directions) toward the intersection of the lines of terminals. Therefore, it is possible to further enhance the ability of mitigating thermal stress.

An electronic module of the present invention is arranged such that an electronic component is mounted on any one of the above multilayer wiring boards. Further, an electronic device of the present invention includes the electronic module. With this arrangement, it is possible to realize an electronic module and an electronic device that allows for mitigation of stress (thermal stress) caused by difference in thermal expansion between the multilayer wiring board and the electronic component.

The present invention is not limited to the aforementioned embodiments and is susceptible of various changes within the scope of the accompanying claims. That is, an embodiment obtained by suitable combinations of technical means varied within the scope of the patent claims set forth below is also included within the technical scope of the present invention.

### INDUSTRIAL APPLICABILITY

A multilayer wiring board of the present invention makes it possible to mitigate thermal stress without impairing the freedom of wiring design. Therefore, by decreasing stress (thermal stress) caused by difference in thermal expansion between the multilayer wiring board and the electronic component due to heating and/or thermal dissipation, it is possible to reduce cracks and poor soldering of a package of an electronic component such as a camera module and IC. In addition, it is possible to mount a camera module (imaging device) for use in a mobile phone or digital still camera with high precision.

1. A multilayer wiring board comprising:
a plurality of opened wiring layers being stacked on top of each other and respectively having openings, which form a through hole penetrating in a direction in which the opened wiring layers are stacked; and
a sandwiched wiring layer disposed between the opened wiring layers, wherein
the sandwiched wiring layer overlaps at least part of the opening of the opened wiring layer and has a blocking section that blocks the through hole.

2. The multilayer wiring board according to claim 1, wherein
the blocking section is formed so as to overlap a whole area of the opening of the opened wiring layer.

3. The multilayer wiring board according to claim 1, wherein
the sandwiched wiring layer is more flexible than the opened wiring layer.

4. The multilayer wiring board according to claim 3, wherein
the sandwiched wiring layer is a flexible substrate.

5. The multilayer wiring board according to claim 1, wherein
the sandwiched wiring layer has an aperture that gets through to the through hole.

6. The multilayer wiring board according to claim 1, further comprising:
terminals through which an electronic component is surface-mounted, wherein
the opening of the opened wiring layer is formed in a terminal-formed area of the opened wiring layer.

7. The multilayer wiring board according to claim 6, wherein
the opening of the opened wiring layer is formed so as to cut a line that couples the corresponding terminals arranged at opposite positions.

8. The multilayer wiring board according to claim 6, wherein
the opening of the opened wiring layer is formed so as to extend from an inside of a terminal-formed area toward outer edges of the opened wiring layer, passing through an intersection of lines of terminals, which lines are arranged along respectively different directions.

9. The multilayer wiring board according to claim 3, wherein
the sandwiched wiring layer is made from aramid or polyimide resin.

10. The multilayer wiring board according to claim 9, wherein
the sandwiched wiring layer is a thin film.

11. The multilayer wiring board according to claim 1, wherein
the opened wiring layers and the sandwiched wiring layer are made from the same material.

12. An electronic module in which an electronic component is mounted on a multilayer wiring board according to claim 1.

13. An electronic device including an electronic module according to claim 12.
